(19) United States
(12) Patent Application Publication
(10) Pub. No.: US 2014/0307499 A1
(43) Pub. Date: Oct. 16, 2014

(54) BOOSTER CIRCUIT

(71) Applicant: PANASONIC CORPORATION, Osaka (JP)

(72) Inventor: Yukimasa HAMAMOTO, Kyoto (JP)

(21) Appl. No.: 14/317,420

(22) Filed: Jun. 27, 2014

Related U.S. Application Data
(63) Continuation of application No. PCT/JP2013/000695, filed on Feb. 8, 2013.

(30) Foreign Application Priority Data
Feb. 28, 2012 (JP) 2012-041535

(51) Int. Cl. G11C 7/12; G11C 11/16; H02M 3/07; G11C 13/00

(52) U.S. Cl. CPC G11C 7/12; G11C 13/0021; G11C 11/165; H02M 3/07
USPC 365/148; 365/158; 365/189.07; 323/311

(57) ABSTRACT

A booster circuit configured to boost a supplied voltage and provide a booster circuit output includes: an oscillator circuit configured to generate a clock signal; a charge pump circuit configured to provide a charge pump output by boosting the supplied voltage with the use of the clock signal; a detection circuit configured to detect a voltage of the booster circuit output and output a detection signal; and an output circuit configured to connect and disconnect the charge pump output to and from the booster circuit output. The oscillator circuit controls activation and deactivation of an output of the oscillator circuit in accordance with the detection signal, and the output circuit controls disconnection of the output circuit in accordance with the detection signal.

### CROSS-REFERENCE TO RELATED APPLICATIONS

This is a continuation of International Application No. PCT/JP2013/000695 filed on Feb. 8, 2013, which claims priority to Japanese Patent Application No. 2012-041535 filed on Feb. 28, 2012. The entire disclosures of these applications are incorporated by reference herein.

### BACKGROUND

The present disclosure relates to booster circuits for use in semiconductor memories and the like, and in particular, to booster circuits which reduce overshoots and ripples of boosted voltages.

The semiconductor memories such as flash memories require a voltage higher than a voltage of external power sources to perform writing, erasing, and reading of data. The semiconductor memories include a booster circuit which has an oscillator circuit configured to generate a clock signal, a charge pump circuit configured to boost a supplied voltage by using the clock signal, and a detection circuit configured to detect the boosted voltage and perform control such that the boosted voltage is maintained within a voltage range.

The voltage range within which a boosted voltage is maintained has influence on stable operation of circuits to which the boosted voltage is supplied. In particular, the upper limit of the voltage range of the boosted voltage affects and degrades the characteristics of transistors to which the boosted voltage is supplied. It is therefore necessary to narrow the voltage range of the boosted voltage.

According to a conventional technique, a detection circuit is configured to compare two voltages including a first comparative voltage and a second comparative voltage, and a charge pump circuit performs boosting with its normal voltage-boosting efficiency until a booted voltage reaches the first comparative voltage that is the lower comparative voltage. When the boosted voltage exceeds the first comparative voltage, the voltage-boosting efficiency is reduced by reducing the frequency of a clock signal. The charge pump circuit is switched between the active state and the inactive state in accordance with the results of comparison between the boosted voltage and the second comparative voltage that is the higher comparative voltage, thereby narrowing the voltage range of the boosted voltage (see Japanese Unexamined Patent Publication No. 2005-190533).

### SUMMARY

According to the conventional technique, however, a time lag between a point in time at which the detection circuit determines the comparison results in the vicinity of the second comparative voltage and a point in time at which the charge pump circuit is switched to the active state or the inactive state allows unnecessary clock pulses to be input to the charge pump circuit. Consequently, the boosted voltage is excessively boosted, and an overshoot occurs. In addition, since the voltage-boosting efficiency is reduced when the boosted voltage exceeds the first comparative voltage, the booster circuit according to the conventional technique cannot follow abrupt changes in load, and the boosted voltage may disadvantageously drop.

Moreover, when the upper limit of the boosted voltage is high, the booster circuit needs to include, as the transistors to which the boosted voltage is supplied, high-breakdown voltage transistors having a thick oxide film. This will increase the circuit area and manufacturing costs.

It is therefore an object of the present disclosure to provide a booster circuit of which a voltage range of a boosted voltage is narrowed without reducing voltage-boosting efficiency of the booster circuit.

The booster circuit of the present disclosure includes an output circuit between a charge pump output and a booster circuit output, and is configured to perform switching between connection and disconnection of the output circuit in accordance with the booster circuit output.

Specifically the booster circuit of the present disclosure is configured to boost a supplied voltage and output a boosted voltage to a first terminal, and includes: an oscillator circuit configured to generate a clock signal; a charge pump circuit configured to boost the supplied voltage by using the clock signal and output the boosted voltage to a second terminal; a detection circuit configured to detect the voltage at the first terminal and output a detection signal; and an output circuit configured to disconnect the first terminal from the second terminal, wherein the oscillator circuit controls activation and deactivation of an output of the oscillator circuit in accordance with the detection signal, and the output circuit controls disconnection of the output circuit in accordance with the detection signal.

With this configuration, when the booster circuit output reaches a predetermined voltage, the output circuit disconnects the charge pump output from the booster circuit output. Accordingly, even when deactivation of the oscillator circuit is delayed and the charge pump output continues to be boosted for a short period, boosting of the booster circuit output is immediately stopped. Thus, the voltage range of the boosted voltage is narrowed.

According to the present disclosure, the voltage range of the boosted voltage can be narrowed and the circuits to which the boosted voltage is supplied can stably operate. In addition, since the upper limit of the boosted voltage can be lowered, it is possible to reduce degradation in the characteristics of the transistors to which the boosted voltage is supplied.

Further, after the charge pump output is disconnected from the booster circuit output, the charge pump output continues to be boosted for a short period. Accordingly, when the output circuit connects the charge pump output to the booster circuit output in a state where the booster circuit output is lower than the predetermined voltage, the electric charge of the charge pump output boosts the booster circuit output. Consequently, the lower limit of the boosted voltage can be elevated and the voltage range of the boosted voltage can be narrowed.

### BRIEF DESCRIPTION OF THE DRAWINGS

FIG. 1 is a block diagram illustrating a configuration of a booster circuit according to an embodiment of the present disclosure.

FIG. 2 is a circuit diagram illustrating an example of the oscillator circuit of FIG. 1.

FIG. 3 is a circuit diagram illustrating an example of the charge pump circuit of FIG. 1.

FIG. 4 illustrates waveforms of two-phase clock signals in the charge pump circuit of FIG. 3.

FIG. 5 is a circuit diagram illustrating an example of the detection circuit of FIG. 1.

FIG. 6 is a circuit diagram illustrating an example of the output circuit of FIG. 1.

FIG. 7 illustrates how the output circuit of FIG. 6 operates, with reference to the waveforms of signals.

FIG. 8 illustrates how the booster circuit of FIG. 1 operates, with reference to the waveforms of signals.

FIG. 9 is a circuit diagram illustrating another example of the output circuit of FIG. 1.

FIG. 10 illustrates how the output circuit of FIG. 9 operates, with reference to the waveforms of signals.

FIG. 11 is a block diagram illustrating a variation of the booster circuit of FIG. 1.

FIG. 12 is a block diagram illustrating a semiconductor memory including the booster circuit of FIG. 1 or FIG. 11.

### DETAILED DESCRIPTION

An embodiment of the present disclosure will be described below with reference to the drawings.

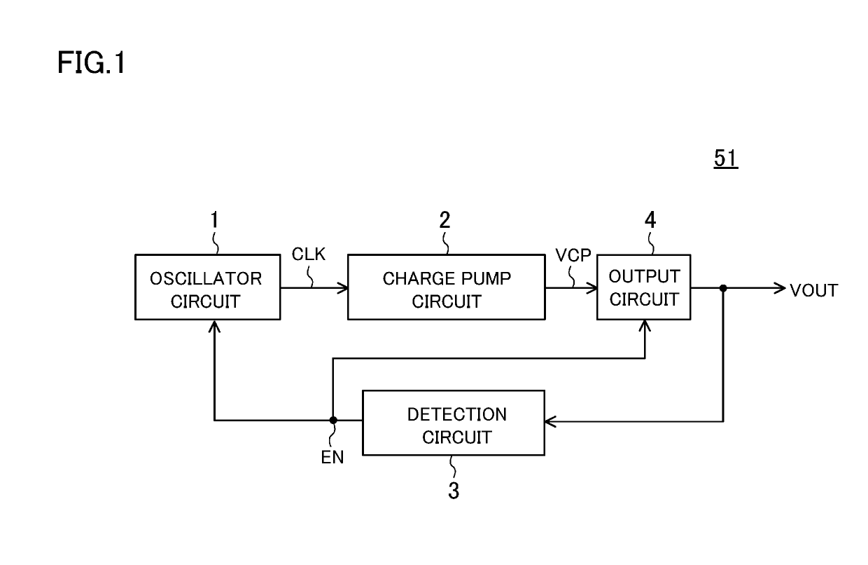

FIG. 1 illustrates a configuration of a booster circuit 51 according to the embodiment of the present disclosure. The booster circuit 51 illustrated in FIG. 1 is configured to provide a booster circuit output VOUT by boosting a supplied voltage. The booster circuit 51 includes an oscillator circuit 1 configured to generate a clock signal CLK, a charge pump circuit 2 configured to provide a charge pump output VCP by boosting the supplied voltage with the use of the clock signal CLK, a detection circuit 3 configured to detect the voltage of the booster circuit output VOUT and output a detection signal EN, and an output circuit 4 configured to connect and disconnect the charge pump output VCP to and from the booster circuit output VOUT. The detection circuit 3 outputs the detection signal EN in accordance with the booster circuit output VOUT.

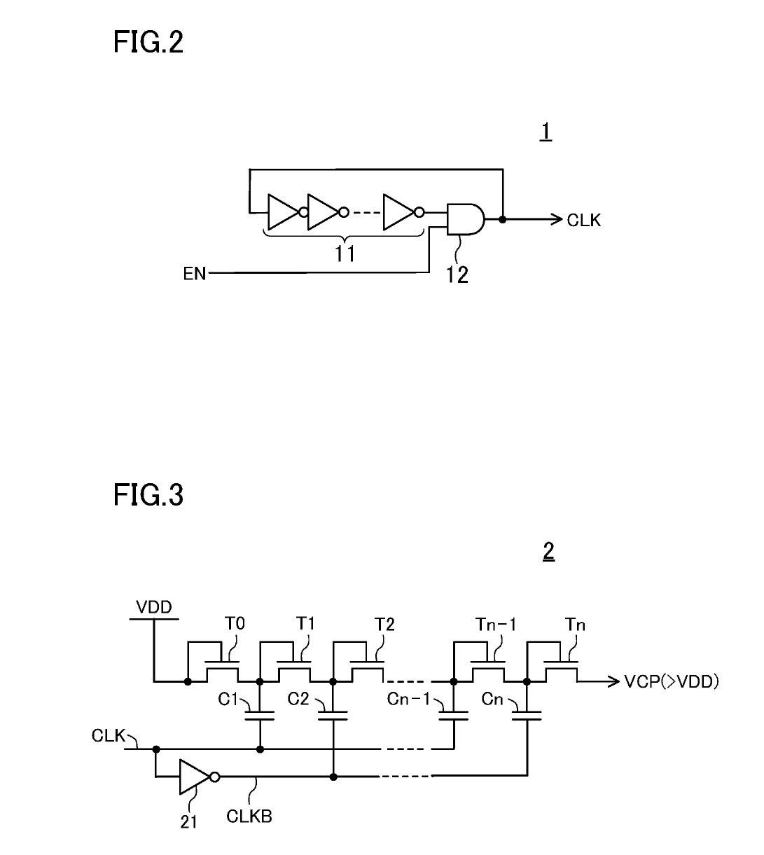

FIG. 2 illustrates an example of the oscillator circuit 1 of FIG. 1. The oscillator circuit 1 illustrated in FIG. 2 includes a chain 11 of inverters and an AND circuit 12 which are connected to each other and thereby constitute a controllable ring oscillator. The oscillator circuit 1 activates the clock signal CLK when the detection signal EN is high, and deactivates the clock signal CLK being low when the detection signal EN is low. It is sufficient that the oscillator circuit 1 deactivates the clock signal CLK, and oscillation of the oscillator circuit 1 does not necessarily need to be stopped.

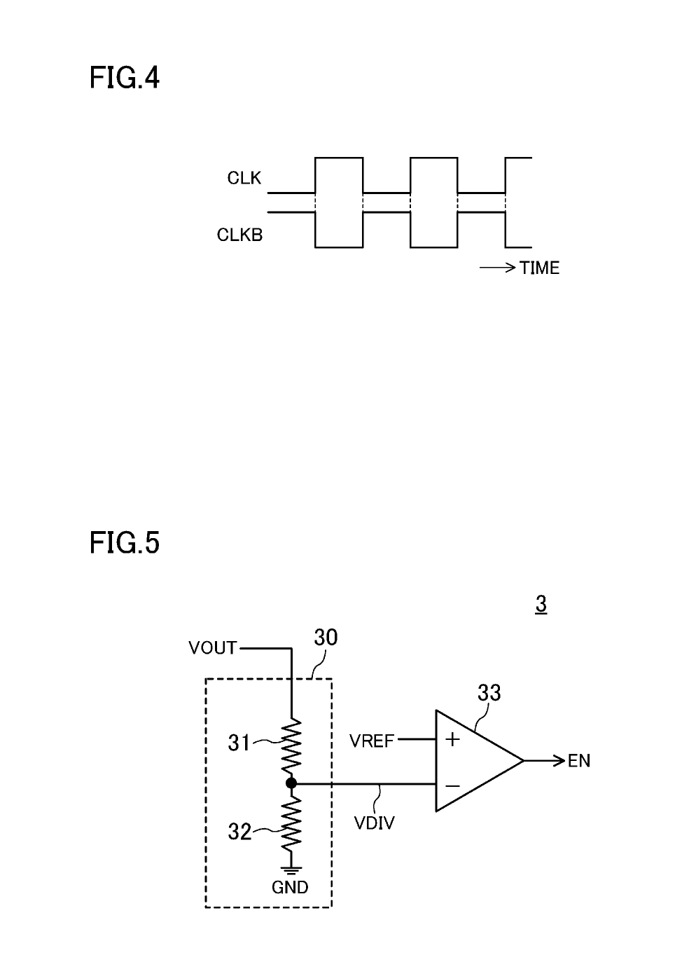

FIG. 3 illustrates an example of the charge pump circuit 2 of FIG. 1. The charge pump circuit 2 illustrated in FIG. 3 is a Dickson charge pump circuit which boosts the supplied voltage VDD by using the clock signal CLK and thereby provides the charge pump output VCP (>VDD) which is a positive boosted voltage. The charge pump circuit 2 includes one inverter 21 configured to generate an inverted clock signal CLKB, n MOS capacitors C1-Cn (where n is an integer), and (n+1) MOS transistors T0-Tn. FIG. 4 illustrates waveforms of the two-phase clock signals CLK and CLKB in the charge pump circuit 2 of FIG. 3.

FIG. 5 illustrates an example of the detection circuit 3 of FIG. 1. The detection circuit 3 illustrated in FIG. 5 includes a voltage divider circuit 30 and a differential amplifier circuit 33. The voltage divider circuit 30 includes resistive elements 31 and 32 connected in series between the booster circuit output VOUT and a ground voltage GND, and outputs a divided voltage VDIV which depends on a resistance ratio between the resistive elements 31 and 32. The differential amplifier circuit 33, which receives the divided voltage VDIV and a reference voltage VREF as inputs, outputs the detection signal EN being low when the divided voltage VDIV is higher than the reference voltage VREF, and outputs the detection signal EN being high when the divided voltage VDIV is lower than the reference voltage VREF.

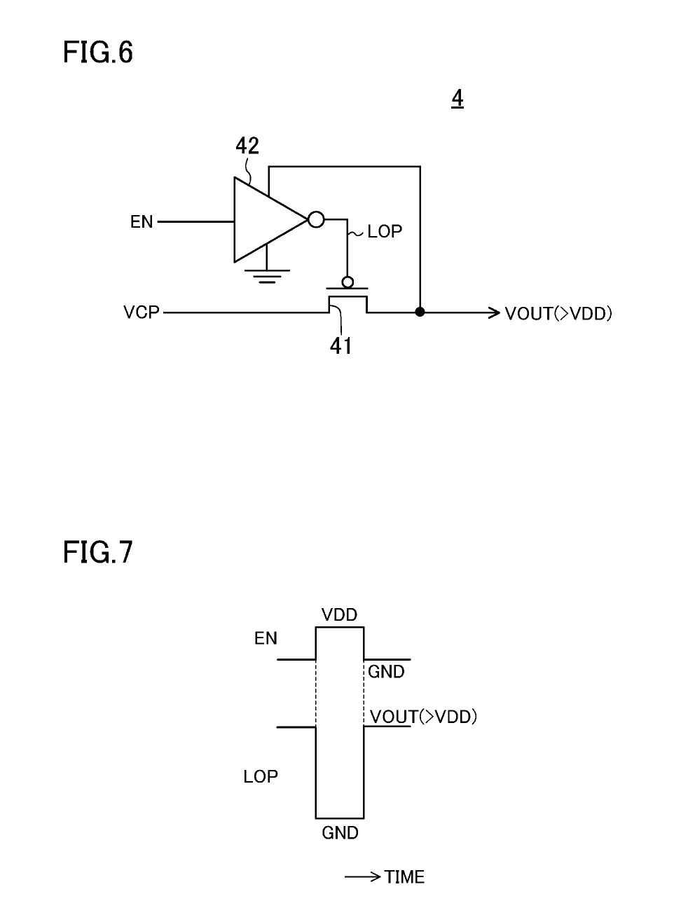

FIG. 6 illustrates a switching circuit as an example of the output circuit 4 of FIG. 1. The output circuit 4 illustrated in FIG. 6 includes a P-channel MOS transistor 41 and a level shift circuit 42 having a function of performing logic inversion. The P-channel MOS transistor 41 has a source terminal connected to the charge pump output VCP and a drain terminal connected to the booster circuit output VOUT (>VDD). The level shift circuit 42 receives the detection signal EN as input, and outputs an output signal LOP having output amplitude which is a change between a voltage of the booster circuit output VOUT and the ground voltage GND. A gate terminal of the P-channel MOS transistor 41 receives the output signal LOP from the level shift circuit 42.

FIG. 7 illustrates how the output circuit 4 of FIG. 6 operates. When the detection signal EN is low (=GND), the booster circuit output VOUT (>VDD) is output as the output signal LOP from the level shift circuit 42. When the detection signal EN is high (=VDD), the ground voltage GND is output as the output signal LOP from the level shift circuit 42.

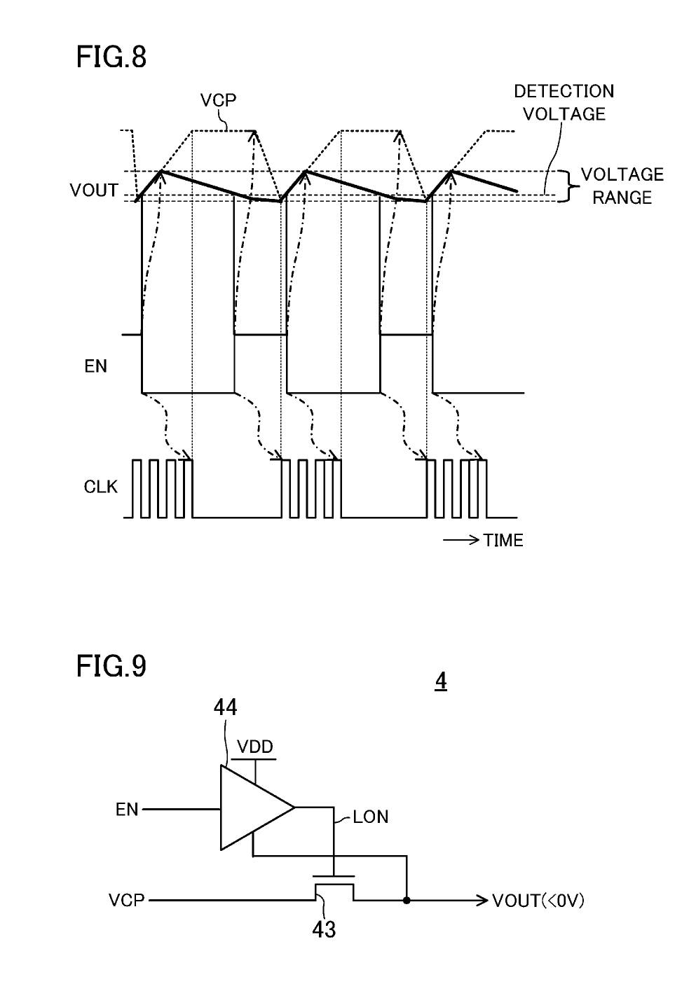

FIG. 8 illustrates how the booster circuit 51 operates. When the voltage of the booster circuit output VOUT becomes higher than a detection voltage set by the detection circuit 3, the detection signal EN becomes low, and the output circuit 4 disconnects the booster circuit output VOUT from the charge pump output VCP. Consequently, the booster circuit output VOUT is no longer boosted. On the other hand, since some pulses of the clock signal CLK are input during a period between the point in time at which the detection signal EN has become low and the point in time at which the oscillator circuit 1 is deactivated, the voltage of the charge pump output VCP becomes higher than that of the booster circuit output VOUT. Thereafter, when loads of the circuits connected to the booster circuit output

VOUT cause the voltage of the booster circuit output VOUT to decrease and become lower than the detection voltage, the detection signal EN becomes high, and the booster circuit output VOUT and the charge pump output VCP are connected to each other. Consequently, the electric charge of the charge pump output VCP reduces speed at which the booster circuit output VOUT drops, or boosts the booster circuit output VOUT.

This operation does not allow unnecessary pulses of the clock signal CLK generated during the period from the transition of the detection signal EN to the deactivation of the oscillator circuit 1 to affect the booster circuit output VOUT, and thereby makes it possible to narrow the voltage range of the booster circuit output VOUT. Further, unlike the foregoing conventional technique, the booster circuit 51 of FIG. 1 can follow abrupt changes in load because it is not required to reduce the voltage-boosting efficiency in the vicinity of the set detection voltage.

FIG. 9 illustrates another example of the output circuit 4 of FIG. 1. The output circuit 4 illustrated in FIG. 9 is suitable for a case where the charge pump circuit 2 provides a negative charge pump output VCP (<0V), and includes an N-channel MOS transistor 43 and a level shift circuit 44 lacking the function of performing logic inversion. The N-channel MOS transistor 43 has a source terminal connected to the charge pump output VCP and a drain terminal connected to the booster circuit output VOUT (<0V). The level shift circuit 44 receives the detection signal EN as input, and outputs an output signal LON having output amplitude which is a change between a power source voltage VDD and a voltage of the booster circuit output VOUT. A gate terminal of the N-channel MOS transistor 43 receives the output signal LON from the level shift circuit 44.

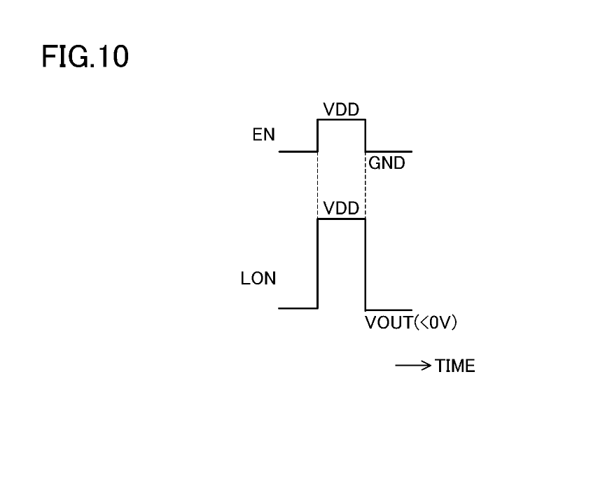

FIG. 10 illustrates how the output circuit 4 of FIG. 9 operates. When the detection signal EN is low (=GND), the booster circuit output VOUT (<0V) is output as the output signal LON from the level shift circuit 44. When the detection signal EN is high (=VDD), the power source voltage VDD is output as the output signal LON from the level shift circuit 44.

The oscillator circuit 1, the detection circuit 3, and the output circuit 4 each may include a MOS transistor or a MOS capacitor of which the thickness of an oxide film is equivalent to or smaller than the thickness of an oxide film in the charge pump circuit 2.

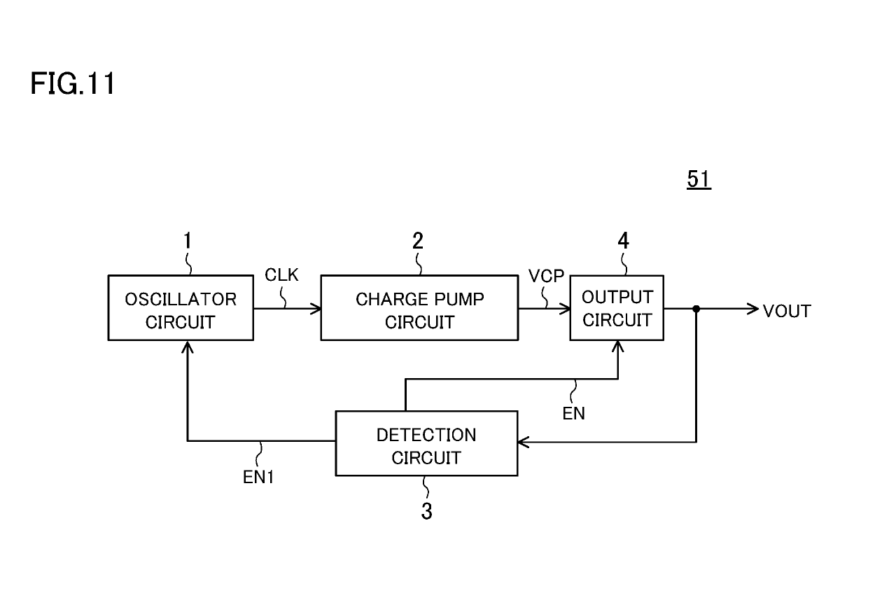

FIG. 11 illustrates another configuration of the booster circuit 51 according to the embodiment of the present disclosure. The detection circuit 3 of FIG. 11 differs from that of FIG. 1 in that the detection circuit 3 of FIG. 11 outputs, in accordance with the booster circuit output VOUT, a detection signal EN and a second detection signal EN1 obtained by delaying the detection signal EN. The components except the detection circuit 3 may be the same as those illustrated in FIG. 1. The output circuit 4 is switched to disconnection in response to the detection signal EN. The oscillator circuit 1 is switched to deactivation in response to the second detection signal EN1 obtained by delaying the detection signal EN. Accordingly, even after the output circuit 4 has been switched to disconnection, the charge pump output VCP is boosted further as compared to the configuration illustrated in FIG. 1.

Since the charge pump output VCP continues to be boosted for a short period even after the output circuit 4 has been switched to disconnection, when the output circuit 4 connects the charge pump output VCP to the booster circuit output VOUT in a state where the booster circuit output VOUT is lower than a predetermined voltage, the electric charge of the charge pump output VCP boosts the booster circuit output VOUT further as compared to the configuration illustrated in FIG. 1. Consequently, the lower limit of the boosted voltage can be elevated, and accordingly, the voltage range of the boosted voltage can be narrowed. However, since the charge pump output VCP is boosted further as compared to the configuration of FIG. 1, it may become necessary to change the voltage withstanding capability of the output circuit 4.

For example, the second detection signal EN1 can be obtained by delaying the detection signal EN at a desired point being intermediate between the output of the detection circuit 3 and the input to the oscillator circuit 1.

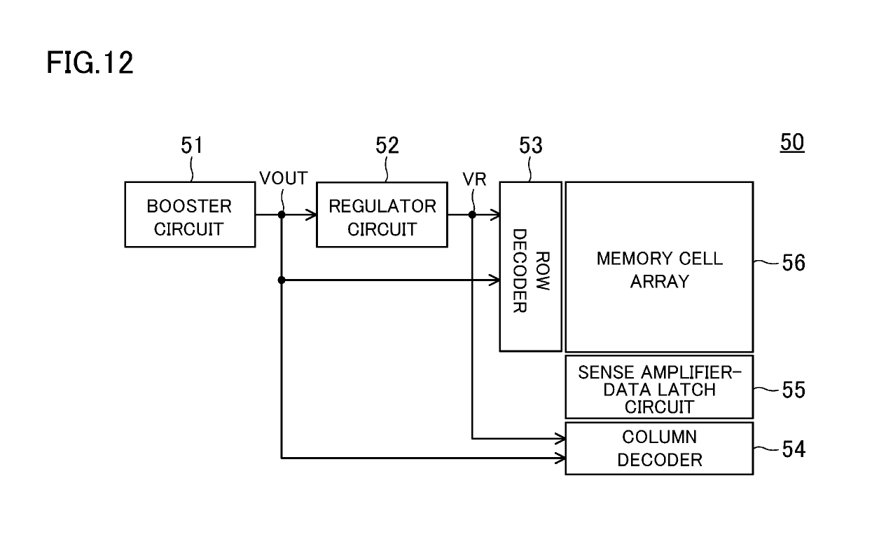

FIG. 12 is a block diagram illustrating a semiconductor memory 50 equipped with the booster circuit 51 of FIG. 1 or FIG. 11. The semiconductor memory 50 illustrated in FIG.

12 includes the booster circuit 51, a regulator circuit 52, a row decoder 53, a column decoder 54, a sense amplifier-data latch circuit 55, and a memory cell array 56. The row decoder 53 and the column decoder 54 are configured to select a memory cell in which writing or reading is performed from the memory cell array 56. The sense amplifier-data latch circuit 55 is a circuit configured to compare and determine data to be written or read. The booster circuit 51 supplies the booster circuit output VOUT serving as a write voltage or a read voltage to the row decoder 53 and the column decoder 54. The regulator circuit 52 generates a stabilized voltage VR from the booster circuit output VOUT, and supply the stabilized voltage VR to the row decoder 53 and the column decoder 54.

The semiconductor memory 50 of FIG. 12 may be provided as a flush memory, a variable resistance type nonvolatile semiconductor memory, or a variable magnetic resistance type nonvolatile semiconductor memory.

The booster circuit of the present disclosure can narrow the voltage range of the boosted voltage and stabilize the operation of the circuits to which the boosted voltage is supplied. In addition, since the upper limit of the boosted voltage can be lowered, it is possible to reduce degradation in the characteristics of the transistors to which the boosted voltage is supplied. The booster circuit of the present disclosure is thus advantageous in that the booster circuit enables highly accurate control of a rewrite voltage in a semiconductor memory and provides the MOS transistors with high reliability. The booster circuit of the present disclosure is useful for variable resistance type nonvolatile semiconductor memories and the like.

What is claimed is:

1. A booster circuit configured to boost a supplied voltage and output a boosted voltage to a first terminal, the booster circuit comprising:
an oscillator circuit configured to generate a clock signal;
a charge pump circuit configured to boost the supplied voltage by using the clock signal and output to a second terminal the boosted voltage which is positive;
a detection circuit configured to detect the voltage at the first terminal and output a detection signal; and
a switching circuit configured to connect and disconnect the first terminal to and from the second terminal, wherein
the oscillator circuit controls activation and deactivation of an output of the oscillator circuit in accordance with the detection signal, and
the switching circuit includes a P-channel MOS transistor in which a gate voltage is controlled in accordance with the voltage at the first terminal such that the first terminal is disconnected from the second terminal in accordance with the detection signal.

2. The booster circuit of claim 1, wherein
the oscillator circuit, the detection circuit, and the switching circuit each include a MOS transistor or a MOS capacitor of which a thickness of an oxide film is equivalent to or smaller than a thickness of an oxide film in the charge pump circuit.

3. A semiconductor memory including the booster circuit of claim 1.

4. A nonvolatile semiconductor memory including the booster circuit of claim 1.

5. A variable resistance type nonvolatile semiconductor memory including the booster circuit of claim 1.

6. A variable magnetic resistance type nonvolatile semiconductor memory including the booster circuit of claim 1.

7. A booster circuit configured to boost a supplied voltage and output a boosted voltage to a first terminal, the booster circuit comprising:
an oscillator circuit configured to generate a clock signal;
a charge pump circuit configured to boost the supplied voltage by using the clock signal and output to a second terminal the boosted voltage which is negative;
a detection circuit configured to detect the voltage at the first terminal and output a detection signal; and
a switching circuit configured to connect and disconnect the first terminal to and from the second terminal, wherein
the oscillator circuit controls activation and deactivation of an output of the oscillator circuit in accordance with the detection signal, and
the switching circuit includes an N-channel MOS transistor in which a gate voltage is controlled in accordance with the voltage at the first terminal such that the first terminal is disconnected from the second terminal in accordance with the detection signal.

8. The booster circuit of claim 7, wherein
the oscillator circuit, the detection circuit, and the switching circuit each include a MOS transistor or a MOS capacitor of which a thickness of an oxide film is equivalent to or smaller than a thickness of an oxide film in the charge pump circuit.

9. A semiconductor memory including the booster circuit of claim 7.

10. A nonvolatile semiconductor memory including the booster circuit of claim 7.

11. A variable resistance type nonvolatile semiconductor memory including the booster circuit of claim 7.

12. A variable magnetic resistance type nonvolatile semiconductor memory including the booster circuit of claim 7.
